(19) United States
(12) Patent Application Publication
(10) Pub. No.: US 2012/0161218 A1
(43) Pub. Date: Jun. 28, 2012

(54) SEMICONDUCTOR DEVICE AND METHOD FOR MANUFACTURING THE SAME

(75) Inventors: Kazunori NIITSUMA, Chuo-ku (JP); Toshiyasu FUJIMOTO, Chuo-ku (JP)

(73) Assignee: ELPIDA MEMORY, INC., Tokyo (JP)

(21) Appl. No.: 13/267,078

(22) Filed: Oct. 6, 2011

(30) Foreign Application Priority Data
Dec. 27, 2010 (JP) 2010-290627
Sep. 1, 2011 (JP) 2011-190650

(51) Int. Cl. H01L 29/78; H01L 21/336

(52) U.S. Cl. 257/296; 438/239; 438/299; 257/330; 438/270; 257/E21.41; 257/E21.409; 257/E29.262

(57) ABSTRACT

In a first method for manufacturing a semiconductor device, an opening is formed in a substrate. A tungsten film is formed on the substrate so as to fill up inside the opening, and then the tungsten film is annealed. The tungsten film is etched back so that the tungsten film remains inside the opening. In a second method for manufacturing a semiconductor device, a laminate body comprising a tungsten film and an insulating film on the tungsten film is formed on a substrate. The laminate body is annealed, and then the laminate body is etched back.

This application is based upon and claims the benefit of priority from Japanese Patent Application No. 2011-190650 filed on Sep. 1, 2011, and Japanese Patent Application No. 2010-290627 filed on Dec. 27, 2010, the disclosure of which is incorporated herein in its entirety by reference.

### TECHNICAL FIELD

The present invention relates to a semiconductor device and method for manufacturing the same.

### RELATED ART

Tungsten has been conventionally used for each part of a semiconductor device.

JP2010-157593 A1 and JP2010-050171 A1 disclose a gate electrode comprising tungsten.

JP2010-251678 A1 and JP2009-289837 A1 disclose a contact plug comprising tungsten.

### SUMMARY OF THE INVENTION

In one embodiment, there is provided a method for manufacturing a semiconductor device, comprising:

forming an opening in a substrate;

forming a tungsten film on the substrate so as to fill up inside the opening;

annealing the tungsten film; and

etching back the tungsten film so that the tungsten film remains inside the opening, after annealing the tungsten film.

In another embodiment, there is provided a method for manufacturing a semiconductor device, comprising:

forming a laminate body comprising a tungsten film and an insulating film on the tungsten film, on a substrate;

annealing the laminate body; and

etching the laminate body after annealing the laminate body.

In another embodiment, there is provided a method for manufacturing a semiconductor device including a Dynamic Random Access Memory, comprising:

forming a gate oxide film on a surface of a semiconductor substrate in a peripheral circuit region;

forming a trench inside the semiconductor substrate in a memory cell region;

forming a gate oxide film and a titanium nitride film in this order on an inner wall of the trench;

forming a first tungsten film on the semiconductor substrate so as to fill up inside the trench;

annealing the first tungsten film;

etching back the titanium nitride film and the first tungsten film so that the gate oxide film, the titanium nitride film, and the first tungsten film remain inside the trench after annealing the first tungsten film;

forming first and second impurity diffusion regions in the semiconductor substrate of the memory cell region in opposite sides of the trench, to obtain an MOS transistor including a buried gate electrode;

forming a laminate body comprising a polysilicon film, a tungsten silicide film, a tungsten nitride film, a second tungsten film, a silicon nitride film, and a silicon oxide film in this order on the semiconductor substrate in the memory cell region and the peripheral circuit region;

annealing the laminate body;

etching the laminate body after annealing the laminate body, to form a bit line on the first impurity diffusion region in the memory cell region and to form a gate electrode on the gate oxide film in the peripheral circuit region;

forming first and second impurity diffusion regions in the semiconductor substrate of the peripheral circuit region in opposite sides of gate electrode, to obtain a planar-type MOS transistor;

forming an interlayer insulating film on the semiconductor substrate of the memory cell region and the peripheral circuit region;

forming a contact hole inside the interlayer insulating film in the memory cell region so as to expose the second impurity diffusion region;

forming a polysilicon film and a titanium film in this order in a lower portion of the contact hole;

forming a titanium nitride film on an inner wall of an upper portion of the contact hole and on a surface of the interlayer insulating film;

forming a third tungsten film so as to fill up inside the contact hole and cover the titanium nitride film on the interlayer insulating film;

annealing the third tungsten film;

etching back the titanium nitride film and the third tungsten film so that the polysilicon film, the titanium film, the titanium nitride film, and the third tungsten film remain inside the contact hole, after annealing the third tungsten film, to form a capacitor contact plug; and

forming a capacitor so as to be connected to the capacitor contact plug.

In another embodiment, there is provided a semiconductor device comprising a tungsten wiring,

wherein at least one crystal grain in the tungsten wiring has a diameter equal to or greater than a width of the tungsten wiring.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a graph showing the relationship between annealing temperature and resistance reduction rate.

FIG. 2 shows the crystal state of tungsten before and after annealing.

FIGS. 3 to 22 explain a method for manufacturing a semiconductor device according to the first exemplary embodiment.

FIG. 23 explains examples of annealing.

FIGS. 24 to 26 mimetically show changes in crystal grains of a tungsten film before and after annealing.

In the drawings, reference numerals have the following meanings: 1; isolation region, 2; active region, 3; silicon oxide film, 4; polysilicon film, 5; hard mask, 6; hard mask pattern, 7; trench, 8; gate oxide film, 9; titanium nitride film, 10; tungsten film, 11; silicon nitride film, 12; photoresist pattern, 13; source and drain regions, 14; polysilicon film. 15; tungsten nitride film, 16; tungsten film, 17; silicon nitride film, 18; silicon oxide film, 19; bit line, 20; gate electrode, 21; photoresist, 22; sidewall, 23; source and drain regions, 24; interlayer insulating film, 25; contact hole, 26; polysilicon film, 27; titanium film, 28; titanium nitride film, 29; tungsten film, 30; contact plug, 31; lower electrode, 32; capacitor insulating film, 33; upper electrode, 34; interlayer insulating film, 35; wiring, 40, 41; crystal grain, 42; photoresist, 43; source and drain regions, 50; semiconductor substrate, 300, 302; single crystal grain, 301; space, Tr1, Tr2, Tr3; MOS transistor

### DETAILED DESCRIPTION OF THE REFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

In a method for manufacturing a semiconductor device according to the first exemplary embodiment, a tungsten film is formed so as to fill up inside an opening provided in a substrate and so as to cover the surface of the substrate. The tungsten film is annealed in this state. The tungsten film remains inside the opening by etching back the tungsten film after annealing the tungsten film.

In a method for manufacturing a semiconductor device according to the second exemplary embodiment, a laminate body comprising at least a tungsten film and an insulating film on the tungsten film is formed on a substrate. The tungsten film is annealed in this state. After annealing, the laminate body is etched.

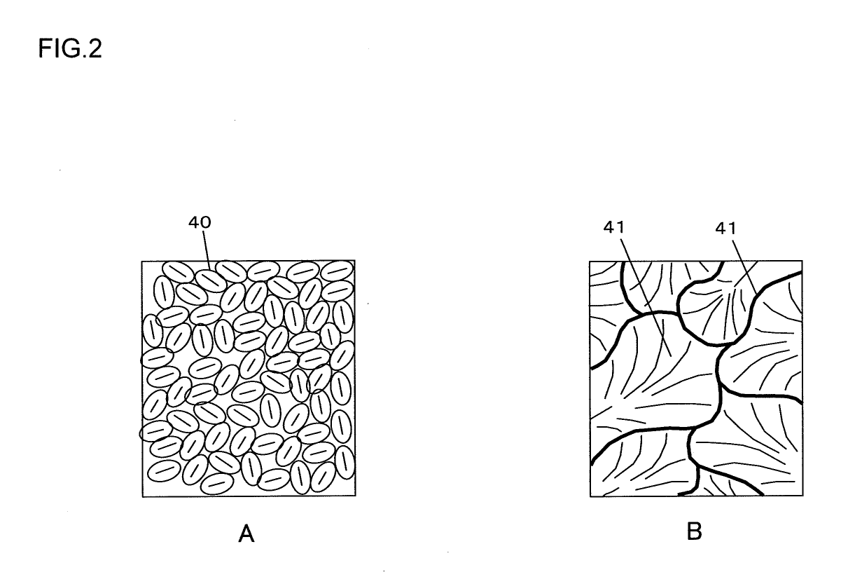

In the first and second exemplary embodiments, the annealing increases the diameter of the crystal grains in tungsten, thereby reducing the resistance of a tungsten film. FIG. 2A shows the state of the crystal grains in the tungsten film before annealing and FIG. 2B shows the state of the crystal grains in the tungsten film after annealing. Tungsten before annealing in FIG. 2A is in a polycrystal state, which is an assembly of fine crystal grains 40. In contrast, by annealing such tungsten, the crystal grains grow to be an assembly of larger crystal grains 41, thereby reducing the resistance.

Also, in the second exemplary embodiment, since annealing is performed in the state where an insulating film is formed on a tungsten film, it is possible to improve the adhesion between the tungsten film and the lower film thereof.

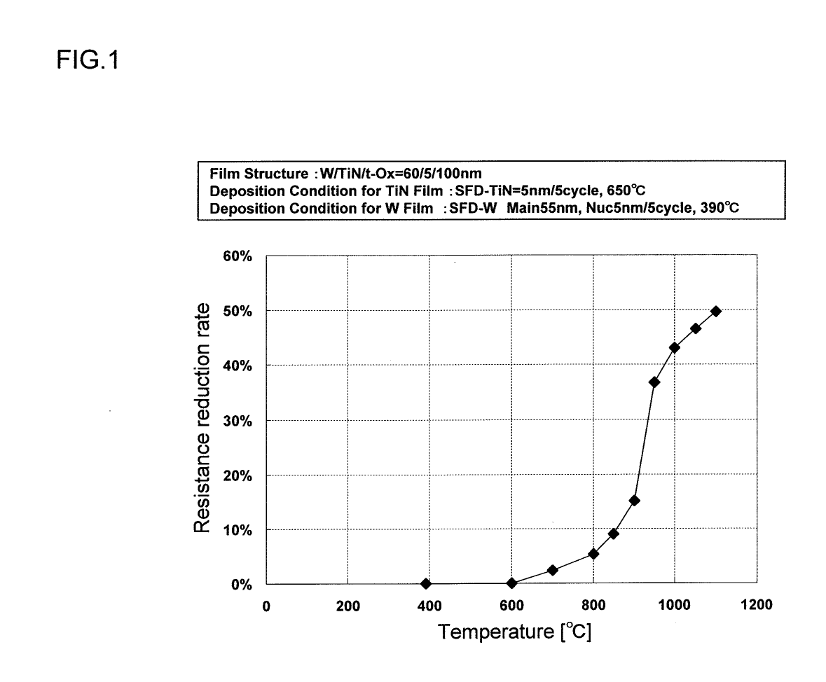

FIG. 1 is a graph showing the relationship between annealing temperature and resistance reduction rate of a tungsten film. A sample was formed by laminating W (tungsten)/TiN (titanium nitride)/t−Ox (thermal oxide film) on a parallel surface. The sum of the thickness of the tungsten film and the thickness of the titanium nitride film was approximately 65 nm. The thickness of the t−Ox film was 100 nm.

The tungsten film is formed by SFD (Sequential Flow Deposition). The SFD continuously performs a nucleus forming process for forming a crystalline nucleus of tungsten by ALD (Atomic Layer Deposition), the ALD repetitively performing a cycle of steps (1) to (4) below several times; and a film forming process in step (5) below for forming a tungsten film on a crystalline nucleus by CVD. The tungsten film is formed at approximately 400° C.:

(1) supplying tungsten fluoride (WF₆) gas to adsorb a tungsten material on the surface of titanium nitride;

(2) pursing the tungsten fluoride (WF₆) gas;

(3) supplying monosilane (SiH₄) gas to reduce the tungsten material adsorbed on the surface of titanium nitride, thereby forming a crystalline nucleus of tungsten;

(4) pursing the monosilane (SiH₄) gas; and

(5) simultaneously supplying tungsten fluoride (WF₆) gas and hydrogen gas to form a tungsten film.

The titanium nitride film was formed by SFD or CVD, and had a thickness of 5 nm. Also, the titanium nitride film was formed at 450 to 650° C.

In FIG. 1, a resistance reduction rate at X ° C. was calculated by the following equation:

[(resistance value at an annealing temperature of 390° C.)−(resistance value at an annealing temperature of X° C.)]/(resistance value at an annealing temperature of 390° C.)×100(%).

It can be understood from FIG. 1 that the resistance reduction rate begins to be greater than 0 from an annealing temperature of 600° C., particularly, that the resistance reduction rate highly increases in the range of 800 to 1000° C. Therefore, the preferable annealing temperature is 800 to 1000° C. When the annealing temperature is lower than 800° C., the resistance reduction rate decreases. Also, if the annealing temperature is more than 1000° C., the increase rate of the resistance reduction rate may decrease and there may be adverse effects to other elements. More preferably, since the crystal state is stable and the resistance reduction rate is large, annealing may be performed at a temperature of 950 to 1000° C.

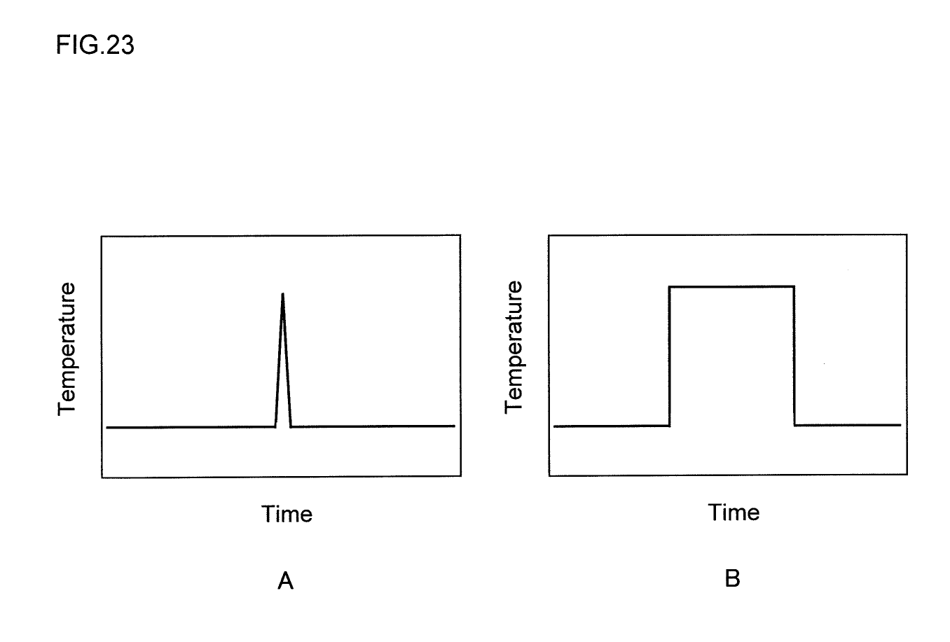

The method for annealing is not particularly limited. The predetermined temperature may be applied to the tungsten film for the predetermined period. Alternatively, the temperature may be continuously decreased or increased during annealing the tungsten film. Preferably, as shown in FIG. 23A, the annealing may be spike annealing applying heat during a very short period or soak annealing applying heat only during a predetermined period. It is possible to minimize adverse effects to other elements due to heat application by performing spike annealing or soak annealing having a short heat applying period. FIG. 1 is a result of soak annealing that applies heat for 8 seconds. Preferably, soak annealing applies heat for 5 to 10 seconds. If heat is applied over 10 seconds, the resistance reduction rate is saturated. If heat is applied less than 5 seconds, the resistance reduction rate becomes small. Since the properties of a transistor becomes worse, the heat application over 30 seconds at 1000° C. is not preferable.

In a method for manufacturing a semiconductor device according to the first and second exemplary embodiments, after forming a tungsten film and before etching back or etching the tungsten film, the tungsten film is annealed. This point distinguishes this method from the related art to which the heat is applied in forming wiring or a film after etching back or etching.

### First Exemplary Embodiment

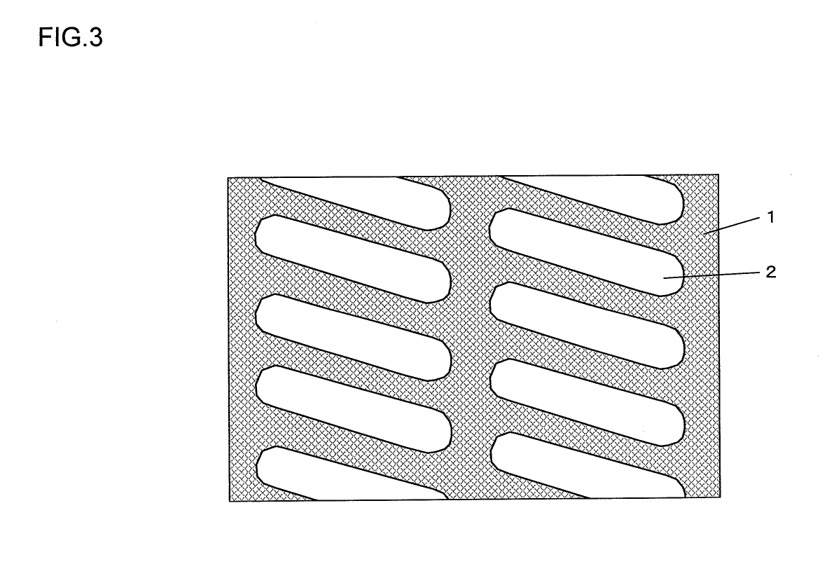

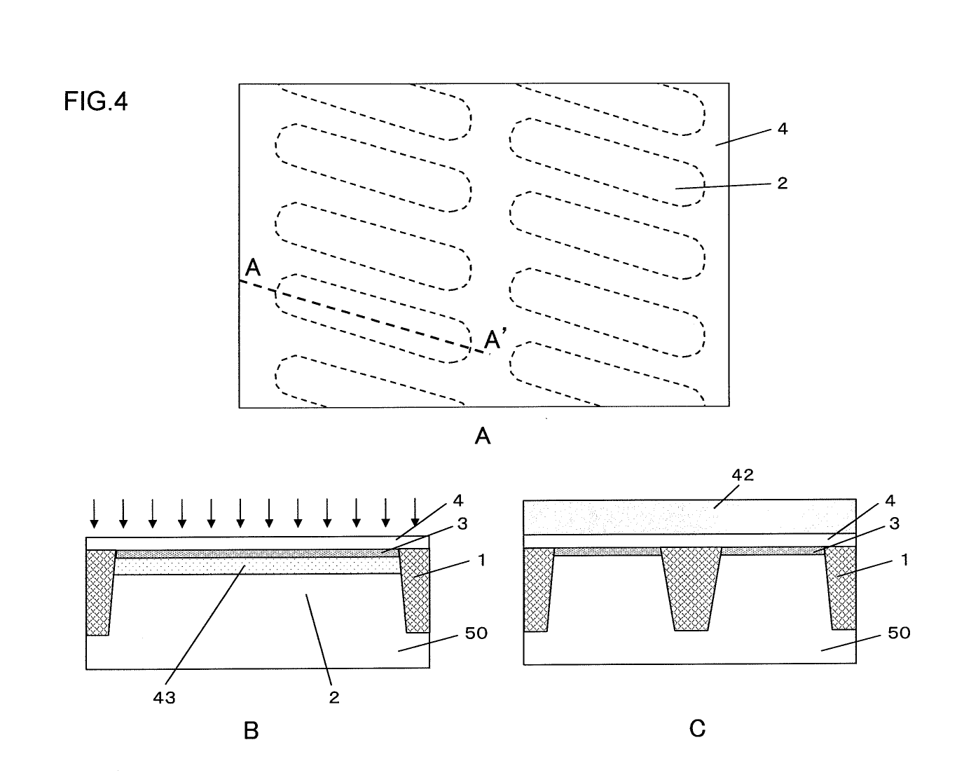

This exemplary embodiment relates to a method for manufacturing a semiconductor device comprising a DRAM (Dynamic Random Access Memory) and will be explained with reference to FIGS. 3 to 22. Also, in FIG. 4 and the following figs., Fig. A is a plane view of a memory cell region, Fig. B is a cross sectional view of A-A direction in Fig. A, and Fig. C is a cross sectional view of a peripheral circuit region. Figs. A and B are schematic views and the numerical values in Figs. A and B are not exact. The active region indicated by broken lines in Fig. A is a perspective view showing the position of the active region.

As shown in FIG. 3, an isolation region 1 having a depth of 250 nm is formed in a memory cell region of a semiconductor substrate 50 by STI (Shallow Trench Isolation), and an active region 2 partitioned by the an isolation region 1 is formed. FIG. 3 is one example of the active region, and the number or disposition of the active regions is not limited to the example in FIG. 3.

As shown in FIG. 4, a silicon oxide film 3 is formed by thermally oxidizing the surface of a semiconductor substrate. Subsequently, a polysilicon film 4 having a thickness of 20 nm is formed on the entire surface of the semiconductor surface by CVD. Subsequently, photoresist 42 covering a peripheral circuit region is formed, and phosphorous, which is n-type impurity, is ion-injected onto the surface of a semiconductor substrate 50 in a memory cell region, to form an LDD (Lightly Dosed Drain) layer 43. The LDD layer 43 is formed so as to have an impurity concentration of 1×10¹⁸ atoms/cm³. The LDD layer 43 becomes a drain region of a buried gate-type MOS transistor in the subsequent processes and is connected with a capacitor contact plug.

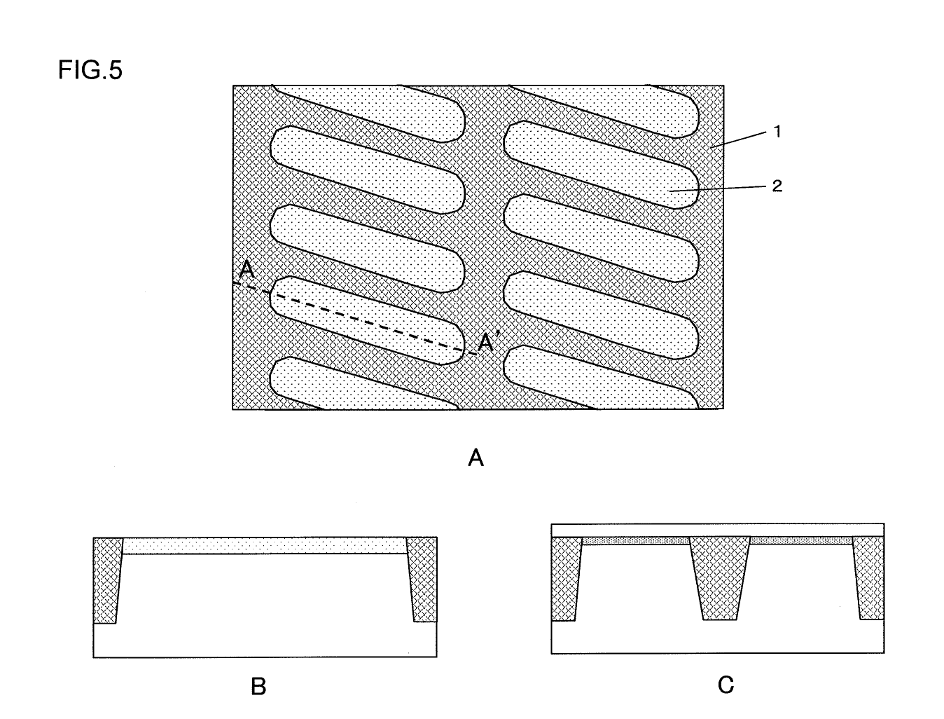

As shown in FIG. 5, a polysilicon film 4 and a silicon oxide film 3 formed on a memory cell region are removed by dry etching method using photoresist 42 (not shown) as a mask. At this time, the silicon oxide film 3 and polysilicon film 4 remained in a peripheral circuit region becomes a part of a gate oxide film and a part of a gate electrode, respectively, in the subsequent processes. Thereafter, the photoresist 42 on the peripheral circuit region is removed.

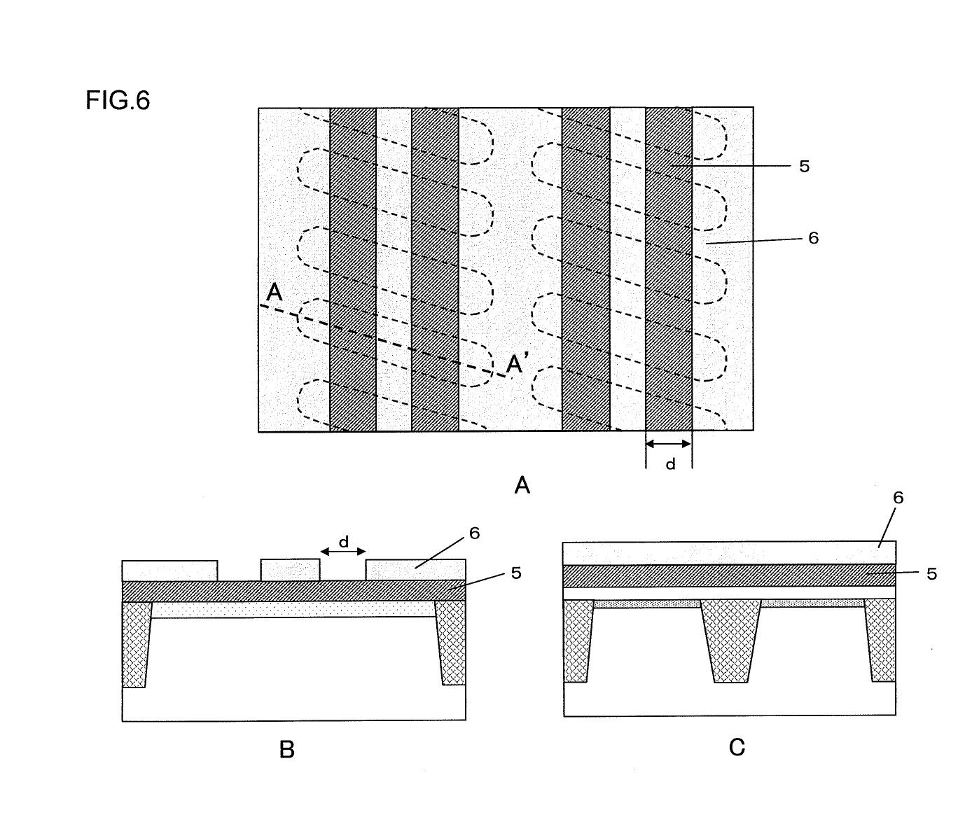

As shown in FIG. 6, a hard mask 5 is formed in the entire surface of a semiconductor substrate 50 by CVD. The example of the hard mask 5 is a silicon oxide film. Next, the lithography technology is used to form the photoresist pattern 6 which covers the overall peripheral circuit region and has line and space pattern on the memory cell region. The photoresist pattern 6 comprises a line pattern crossing a longitudinal direction of an active region 2. In this embodiment, the width d of a space in the photoresist pattern is 50 nm.

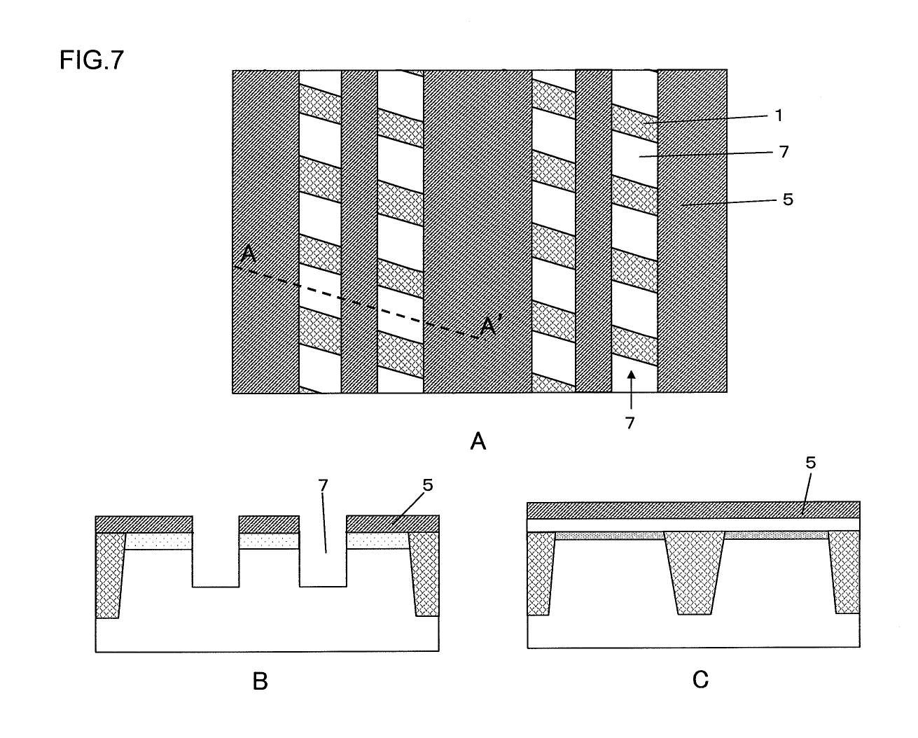

As shown in FIG. 7, in a memory cell region, a photoresist pattern is transferred to a hard mask by dry etching to form a hard mask pattern 5, and thereafter, a trench 7 striding across and interconnecting with a plurality of isolation regions 1 and a plurality of active regions 2 is formed using the hard mask pattern 5. The trench 7 is formed so as to have a width of 50 nm and a depth of 150 nm. At this time, the photoresist pattern 6 is also removed. In this embodiment, the width of the trench 7 is formed so as to preferably have a width of 25 to 60 nm. If the width of the trench 7 is smaller than 25 nm, there is no space to form tungsten inside the trench in the subsequent processes, and if the width of the trench 7 is larger than 60 nm, the properties of a semiconductor device does not vary depending on the resistance of tungsten buried in the trench. Also, the depth of the trench 7 is formed so as to preferably have a depth of 100 to 200 nm. If the depth of the trench 7 is smaller than 100 nm, there is be no space to form a cap insulating film on tungsten in the subsequent processes, and if the width of the trench 7 is larger than 200 nm, it has the same depth as an isolation region 1, and thus, the isolation property becomes worse.

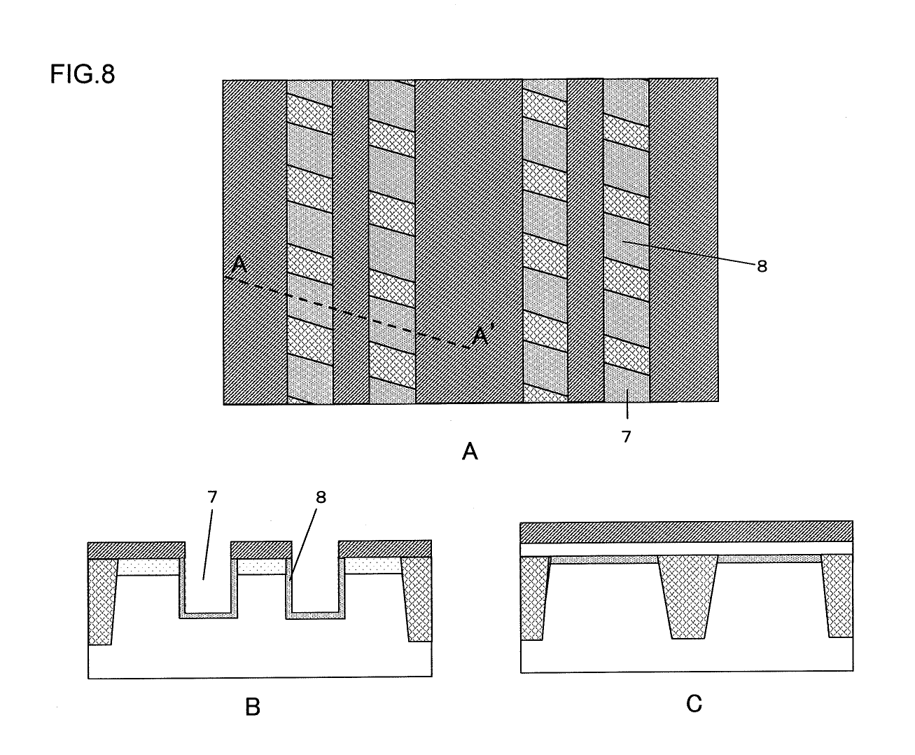

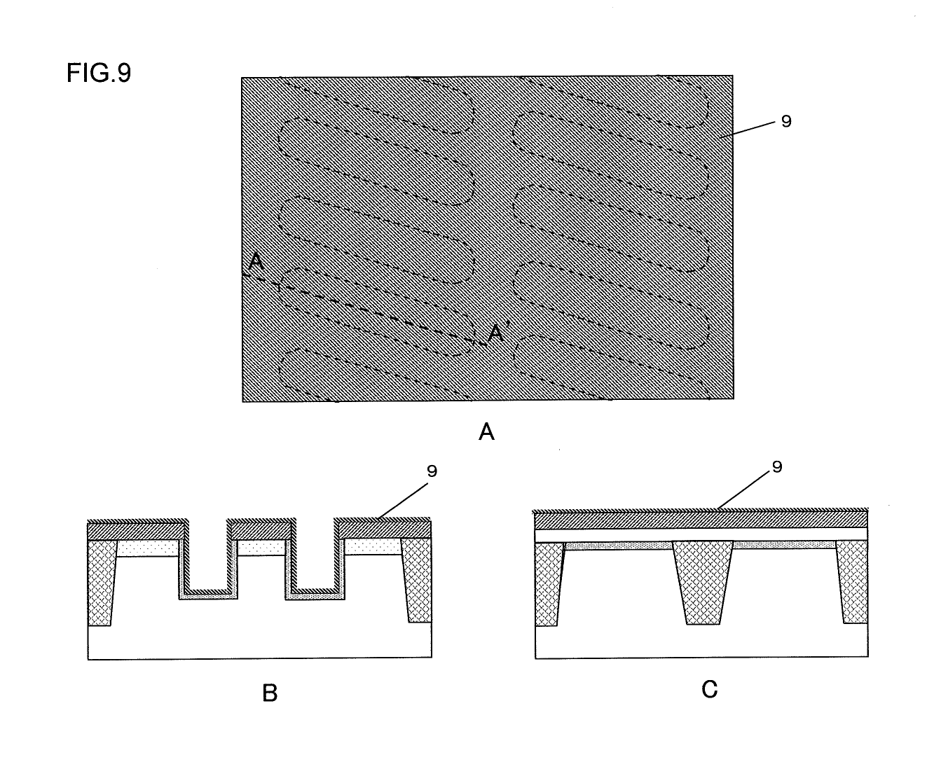

As shown in FIG. 8, by oxidizing the surface of a semiconductor substrate exposed as an inner surface of a trench 7, a gate oxide film 8 comprising a silicon oxide film and having a thickness of 5 nm is formed inside the trench 7. In FIG. 9A and the following Figs. A., a gate oxide film is not shown.

As shown in FIG. 9, a barrier film 9 comprising a titanium nitride film having a thickness of 5 nm is formed on the entire surface of a semiconductor substrate by CVD.

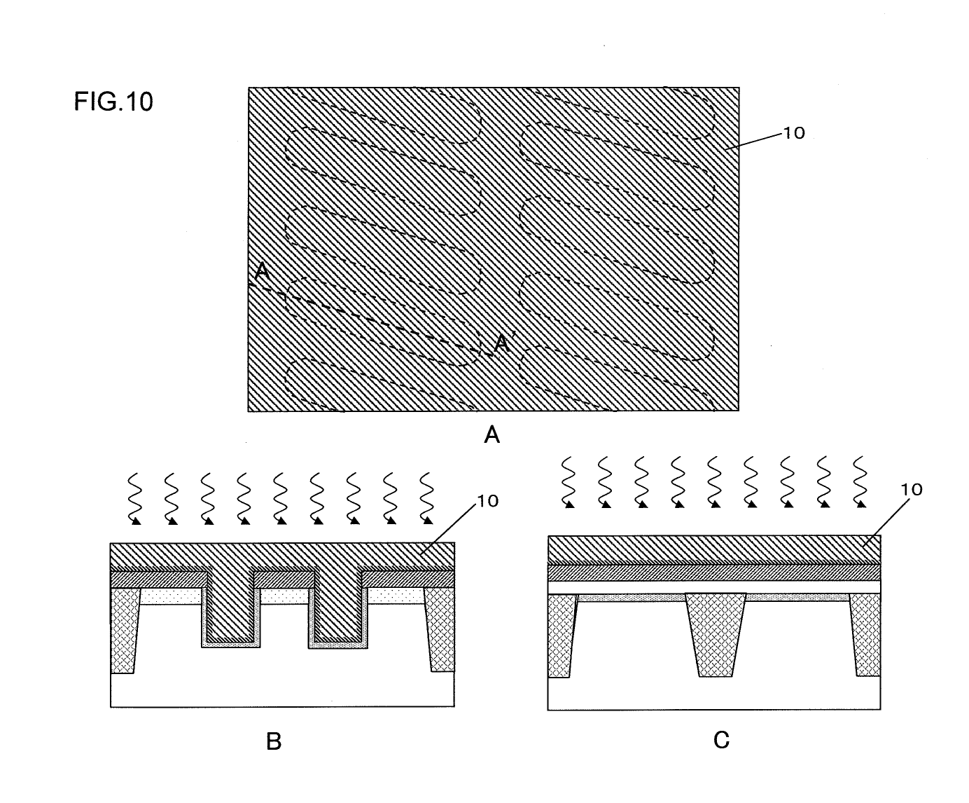

As shown in FIG. 10, a tungsten film 10 having a thickness to completely bury a trench 7 is formed on the entire surface of a semiconductor substrate by SFD (Sequential Flow Deposition). In the initial nucleus forming process by SFD, a crystalline nucleus is formed by ALD comprising alternatively supplying material gas and reduction gas at least once. Thereafter, in the following processes for forming a film, the crystal growth is performed, in which a crystalline nucleus is used as a seed to form the tungsten film, by CVD comprising simultaneously supplying material gas and reduction gas. Specifically, a series of steps (1) to (4) below is performed as a nucleus forming process and step (5) below is performed as a film forming process. The number of repeating SFD and the other conditions is determined, depending on the desired thickness of the tungsten film.

(1) supplying tungsten fluoride (WF₆) gas to adsorb a tungsten material on the surface of the barrier film 9;

(2) pursing the tungsten fluoride (WF₆) gas;

(3) supplying monosilane (SiH₄) gas to reduce the tungsten material adsorbed on the surface of the barrier film 9, thereby forming a tungsten crystalline nucleus;

(4) pursing the monosilane (SiH₄) gas; and

(5) simultaneously supplying tungsten fluoride (WF₆) gas and hydrogen gas to form a tungsten film.

In this embodiment, a tungsten nucleus was formed by repeating a cycle of steps (1) to (4) five times, and thereafter, a tungsten film was formed by performing step (5), so that a tungsten film having a thickness of 60 nm was formed. Since SFD has excellent step coverage, it is possible to completely fill up inside an opening having an aspect ratio (depth/width) as high as the trench 7 with a tungsten film. It is preferable to form the tungsten film inside the opening having an aspect ratio of 10 or less by SFD. In this embodiment, the trench 7 has a width of 50 nm and a depth of 150 nm. Since before forming tungsten film, a gate oxide film 8 having a thickness of 5 nm and a barrier film 9 having a thickness of 5 nm are formed, a remaining space has a width of approximately 30 nm and a depth of approximately 140 nm. Therefore, the aspect ratio is approximately 4.7.

Thereafter, the tungsten film 10 is annealed at nitrogen atmosphere and 1000° C. for 8 seconds. By such annealing, the diameter of the crystal grains in the tungsten film 10 grows, thereby reducing resistance of the tungsten film.

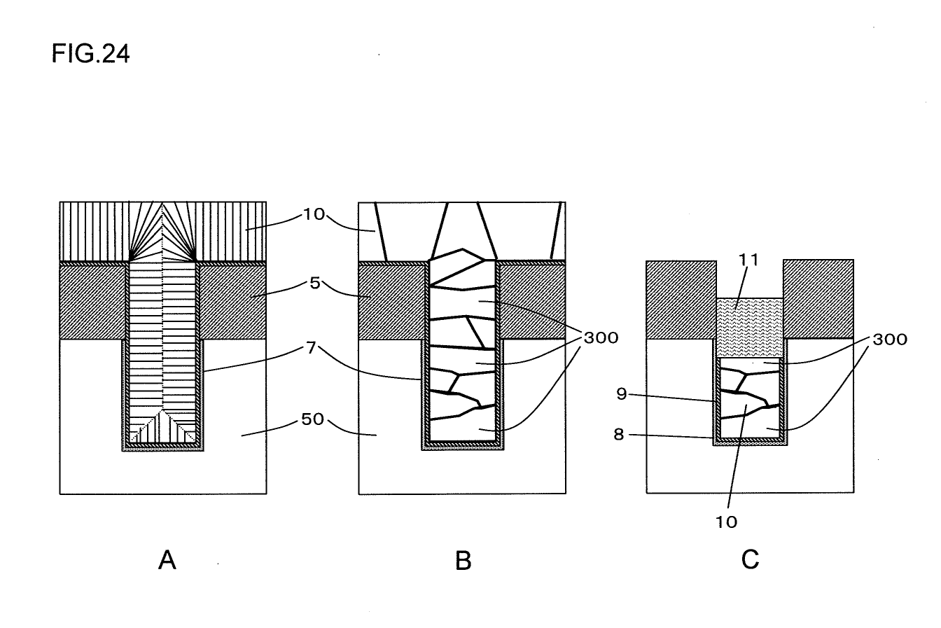

FIG. 24 mimetically shows changes in crystal grains of a tungsten film 10 before and after annealing. FIG. 24A shows a tungsten film before annealing, FIG. 24B shows a tungsten film after annealing, and FIG. 24C shows a state after forming a buried gate electrode. As shown in FIG. 24A, a tungsten film 10 before annealing, i.e., shortly after forming a film is an assembly of tungsten crystals having a micro-particle diameter grown from a tungsten nucleus formed on the surface of a barrier film and are occupied by crystals grown from the surface of a barrier film in a horizontal direction. FIG. 24 is a cross sectional schematic view, but the state of the inside of the trench is also the same in a plane view. When forming a film, tungsten grown from an adjacent tungsten nucleus does not fuse and grows in the direction of a film thickness while maintaining the grain boundary. Therefore, there are extremely many crystal grains. In FIG. 24B, second crystal growth, in which the particle boundary is destroyed and the adjacent crystal grains fuse, occurs by annealing, and thus, there is very large crystal grains. In this case, the tungsten film 10 includes at least one single crystal grain 300 crossing the trench 7 in a width direction. As a result, the grain boundary preventing charge transfer drastically reduces, and thus, it is possible to reduce resistance.

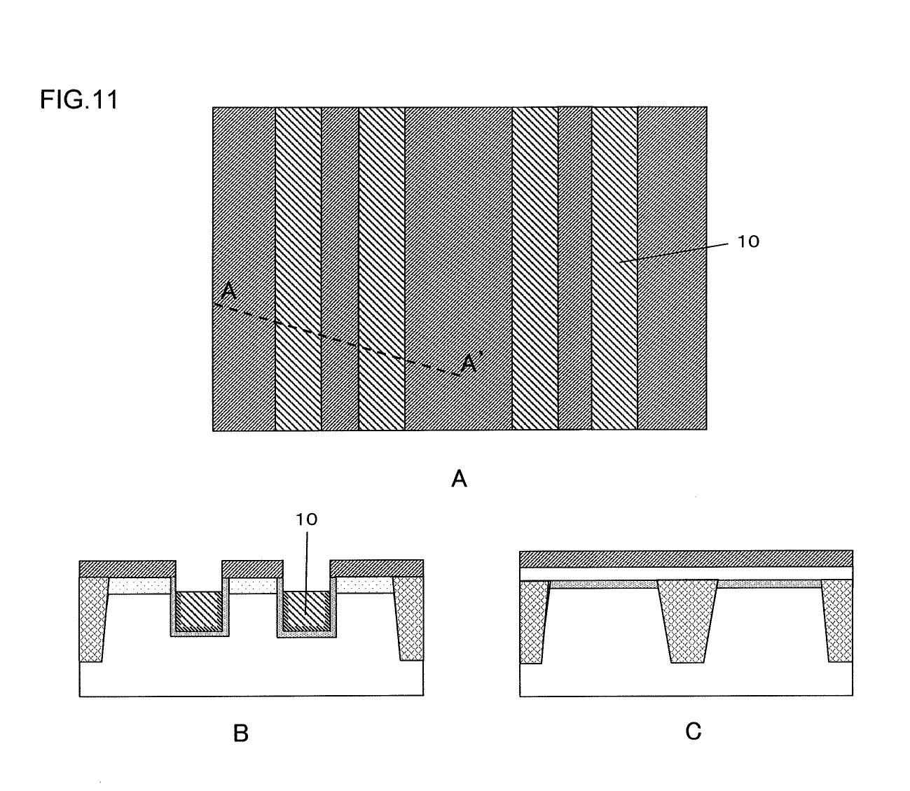

After performing annealing as mentioned above, as shown in FIG. 11, a tungsten film 10 and a barrier film 9 are etched back. Such etching back is performed by dry etching using a chloride containing plasma. After such etching back, the upper surface of the etched back barrier film 9 and tungsten film 10 is below the upper surface of a semiconductor substrate 50 by 70 nm. As a result, the gate oxide film 8 remains in a trench 7, and a buried gate electrode comprising a tungsten film 10 and a barrier film 9 buried in a trench 7 is formed. In DRAM, the buried gate electrode is comprised in word wiring. In this case, the word wiring comprises a barrier film 9 formed along the inside of the trench 7 by interposing a gate oxide film 8, and a tungsten film 10 buried in the barrier film 9. Also, the word wiring comprises a cap insulating film 11 (formed in the subsequent process) in contact with the upper surface of the tungsten film 10 and both the upper surfaces of the barrier film. The tungsten film 10 includes two side surfaces in contact with the inner side surface of the barrier film 9 and at least one single crystal grain 300 crossing the trench 7 in a width direction between the two side surfaces. The surfaces of both ends of the single crystal grain 300 in width-direction of trench 7 contacts with the inner side surface of the barrier film 9. In FIG. 11 and the following Figs. A., a barrier film 9 is not shown.

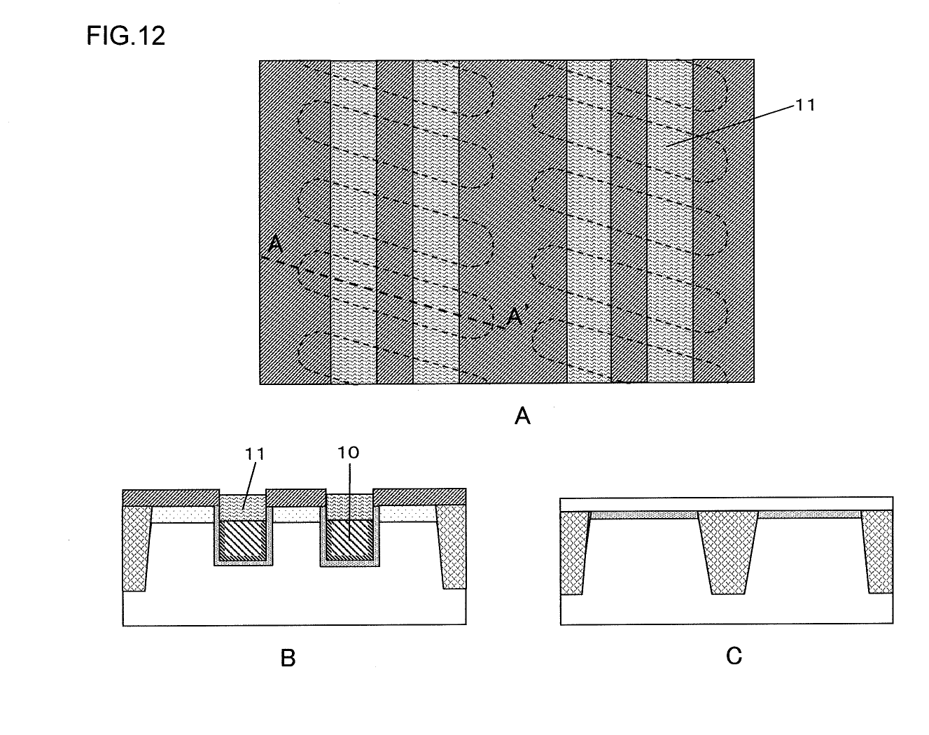

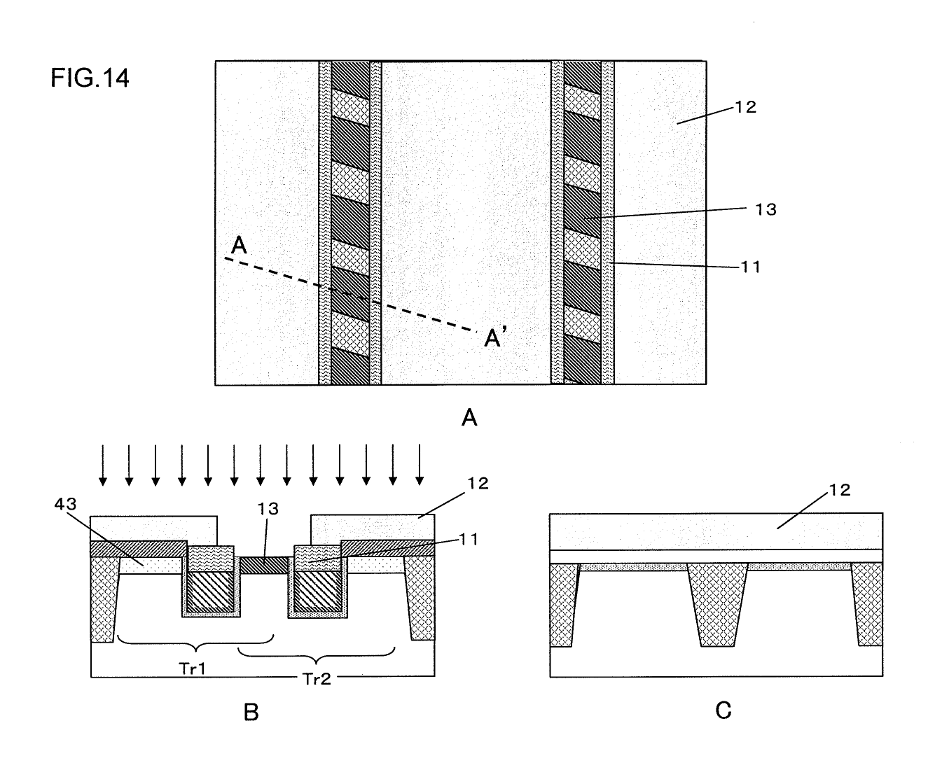

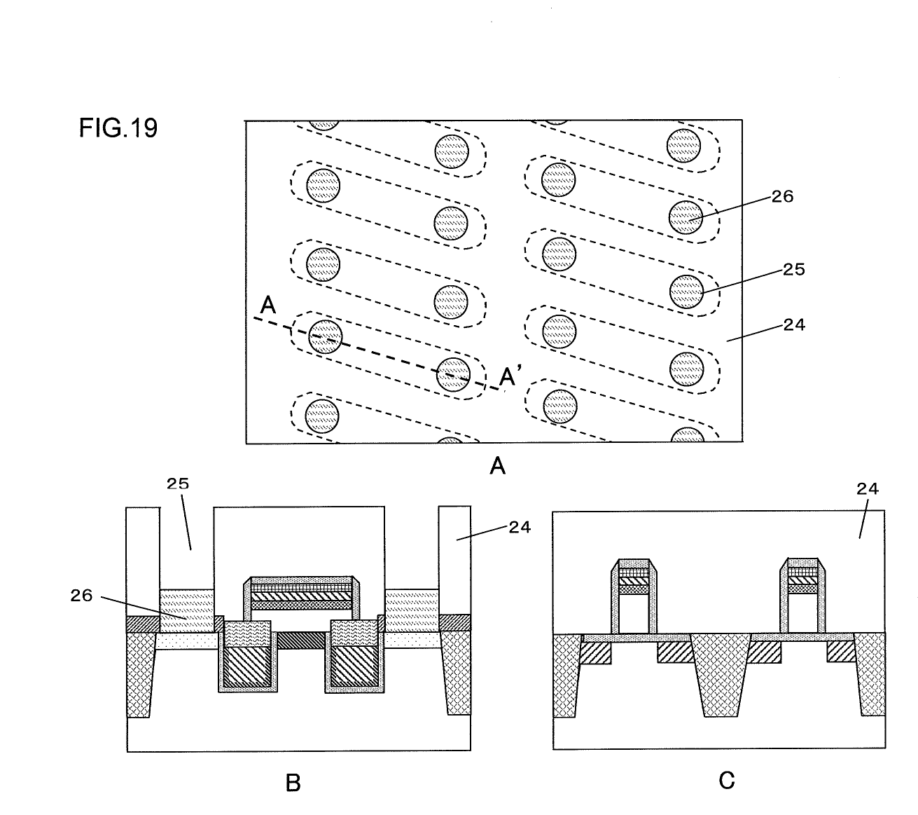

As shown in FIG. 12, after forming a silicon nitride film on the entire surface of a semiconductor substrate by CVD, the etching back is performed to form a cap insulating film 11 comprising the silicon nitride film on a gate electrode. At this time, the cap insulating film 11 is formed so that the upper surface of the cap insulating film 11 is disposed at a position higher than the upper surface of a semiconductor substrate 50. Herein, the upper surface of the cap insulating film 11 is disposed at a position higher by 20 nm than the upper surface of a semiconductor substrate 50. If the upper surface of the cap insulating film is disposed at a position identical to or lower than the upper surface of a semiconductor substrate, the cap insulating film is partially etched in the subsequent processes, such as forming a bit line contact plug (see FIG. 14) or a capacitor contact plug (see FIG. 19), and thus, there is a problem of short circuit between a buried gate electrode and a bit line contact or a capacitor contact plug. In order to avoid such problem, the upper surface of the cap insulating film should be formed so that it is disposed at a position higher than the upper surface of the semiconductor substrate. Subsequently, photoresist (not shown) covering a memory cell region is formed, and a hard mask 5 formed in a peripheral circuit region is removed. Thereafter, photoresist covering a memory cell region is removed.

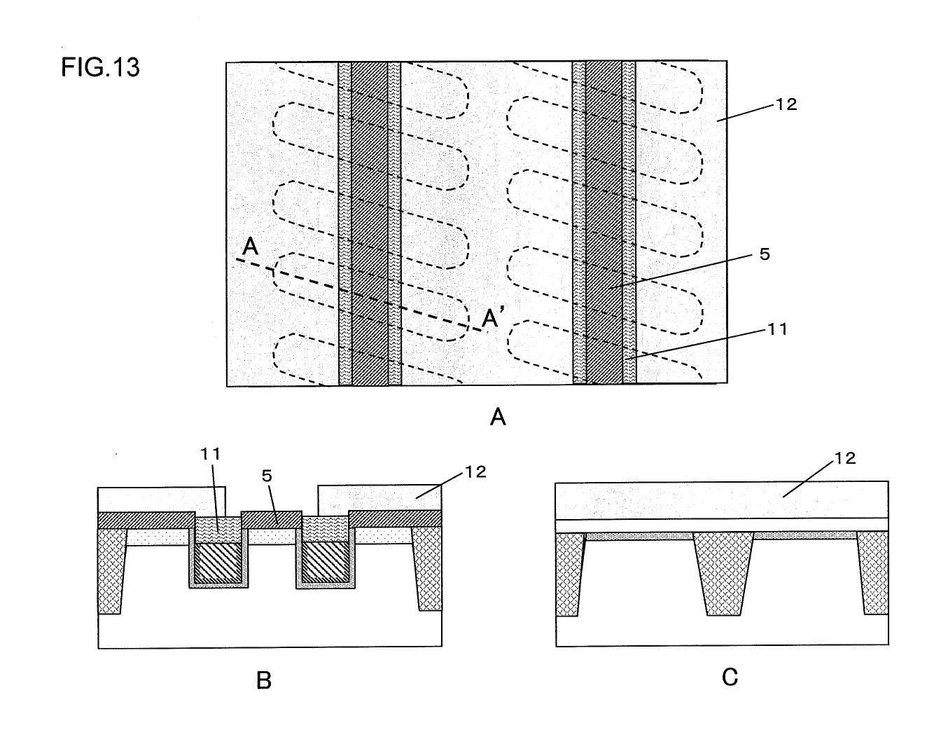

As shown in FIG. 13, a photoresist 12 entirely covering a peripheral circuit region and including a pattern on a memory cell region is formed. This pattern is formed as a straight line pattern striding over a plurality of active regions 2 so as to expose the surface of a hard mask 5 in a region, in which a bit line contact plug is to be formed.

As shown in FIG. 14, a hard mask 5, the surface of which is exposed, is removed by etching using a photoresist 12 and a silicon nitride film 11 as a mask, thereby exposing the surface of a semiconductor substrate, in which a bit line contact plug is to be formed. Subsequently, impurity of phosphorous or arsenic is ion-injected onto the entire surface of the semiconductor substrate, to form an n-type high concentration impurity diffusion region 13 on the surface of the exposed semiconductor substrate in both sides of a gate electrode. The high concentration impurity diffusion region 13 is formed so as to have a concentration of 8×10²° atoms/cm³ and is a source region 13 of a transistor. If a bias application state is reversed, a source region and a drain region are reversed. As a result, MOS transistors Tr1 and Tr2 including a buried gate electrode in one active region are completed. For example, Tr1 comprises a gate oxide film 8, a buried gate electrode including a tungsten film 10, and source and drain regions 13, 43. Also, in Fig. B of this embodiment, the two MOS transistors Tr1 and Tr2 share the source region 13.

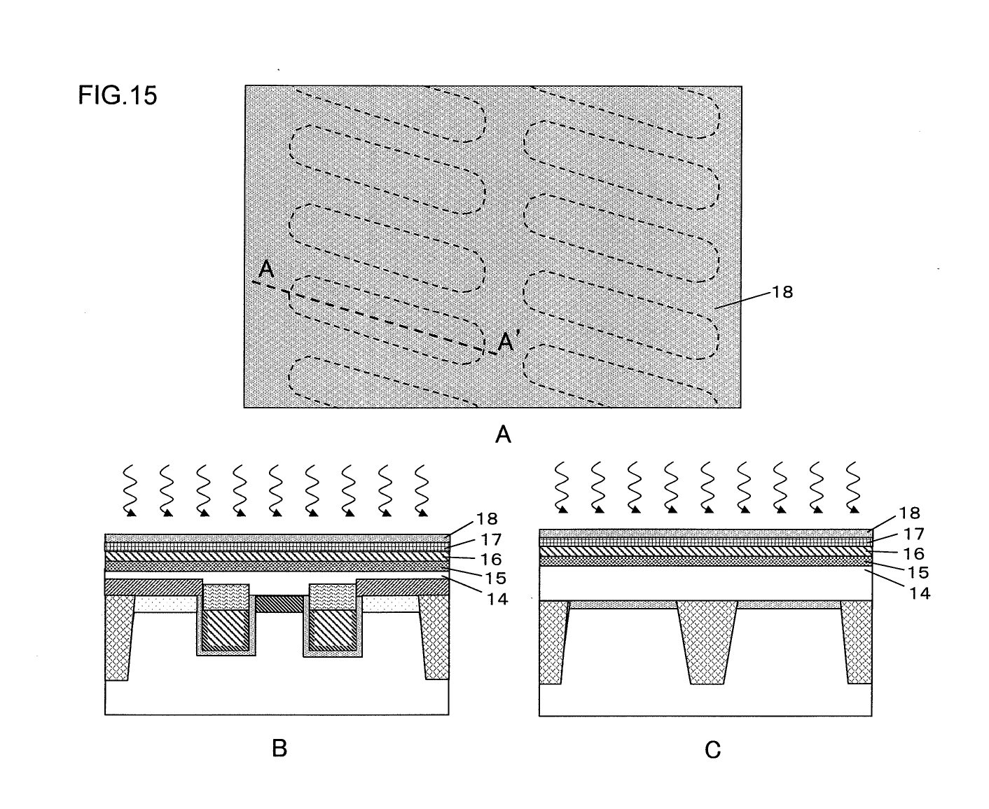

As shown in FIG. 15, after removing photoresis 12, an n-type impurity containing polysilicon film 14 having a thickness of 20 nm, a tungsten nitride film 15 having a thickness of 10 nm, a tungsten film 16 having a thickness of 30 nm, a silicon nitride film 17 having a thickness of 50 nm, and a silicon oxide film 18 having a thickness of 20 nm are formed in order on the entire surface of a semiconductor substrate (hereinafter, a laminate of films 14 to 18 may be referred to as “laminate body”). Although not shown in FIG. 15, a very thin tungsten silicide film having a thickness of approximately 1 nm is formed between the polysilicon film 14 and tungsten nitride film 15. The tungsten film 16 is formed by SFD under the same condition as the tungsten film 10. Also, the polysilicon film 14, tungsten nitride film 15, silicon nitride film 17, and silicon oxide film 18 are formed by CVD.

Also, since in a peripheral circuit region, a polysilicon film 14 is further formed on a previously formed polysilicon film 4, the polysilicon film is thicker than that of a memory cell region. Thereafter, the laminate is annealed for 8 seconds at 1000° C. Such annealing increases the diameter of the crystal grains in the tungsten film 16, thereby reducing the resistance of the tungsten film 16.

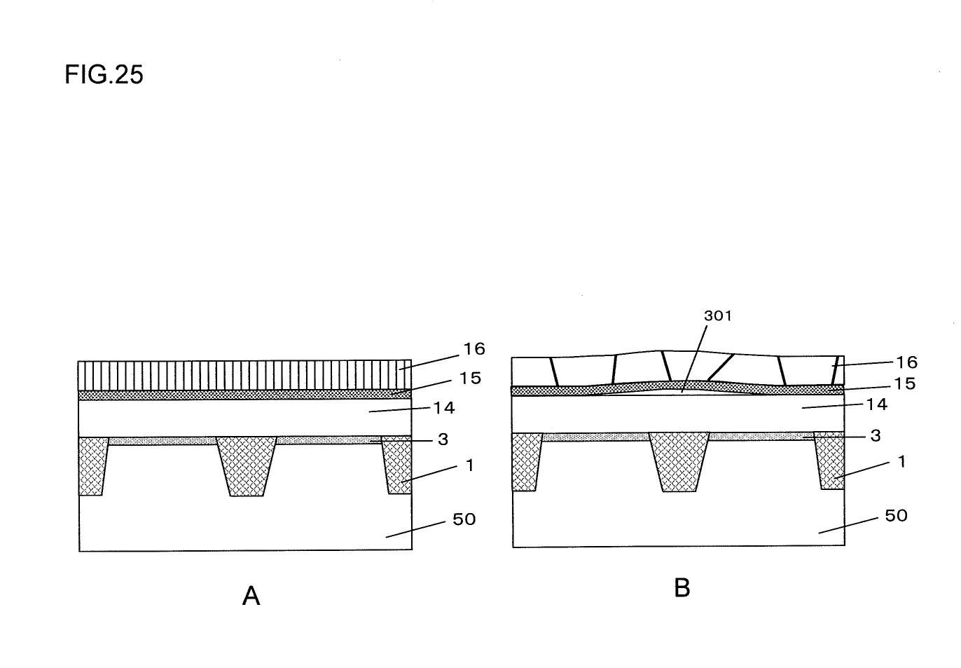

FIG. 25A shows the state where the surface of a tungsten film 16 is exposed before annealing, and FIG. 25B shows the state where the surface of a tungsten film 16 is exposed after annealing. If annealing is performed when the surface of the tungsten film 16 is exposed as shown in FIG. 25A, i.e., before forming a silicon nitride film 17 and a silicon oxide film 18, a space 301 is generated between a tungsten nitride film 15 and a polysilicon film 14 by peeling, as shown in FIG. 25B, and thus, there is a problem of high contact resistance.

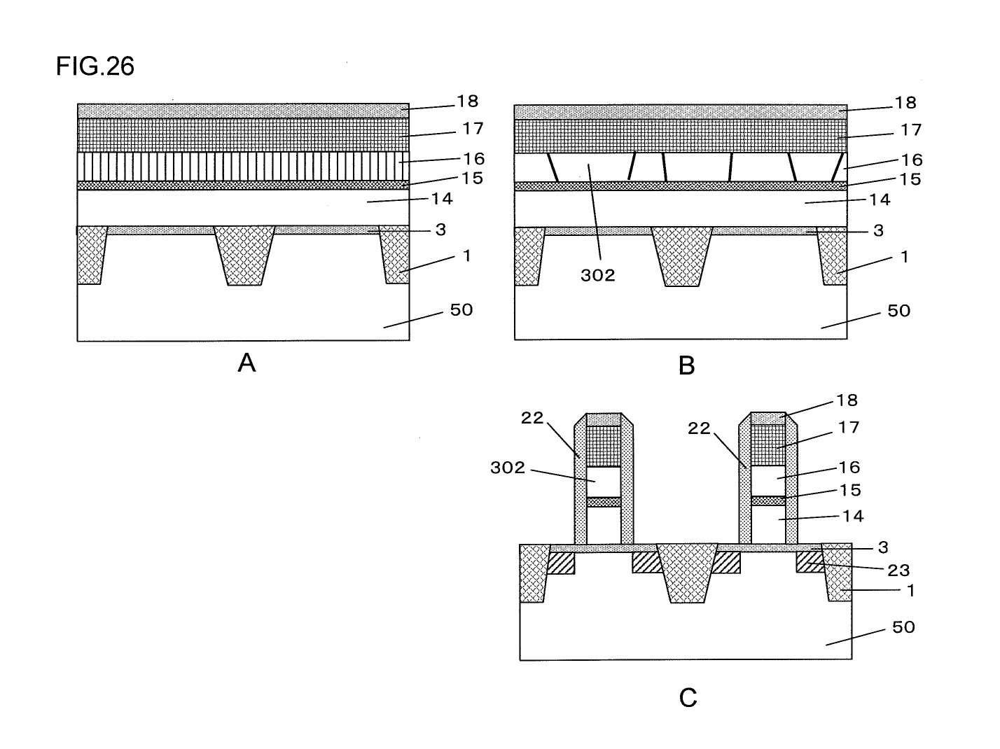

FIG. 26A shows the state where the surface of a tungsten film 16 is covered with the tungsten nitride film 17 and silicon oxide film 18 before annealing. FIG. 26B shows the state where the surface of a tungsten film 16 is covered with the tungsten nitride film 17 and silicon oxide film 18 after annealing, and FIG. 26C shows the state where a gate electrode is completed. In this embodiment, as shown in FIG. 26A, the upper surface of the tungsten film 16 is annealed while it is covered with a silicon nitride film 17 and a silicon oxide film 18. As a result, as shown in FIG. 26A, the tungsten film 16, which was an assembly of crystal grains having a small diameter before annealing, is changed so as to include crystal grains having a large diameter by the second crystal growth, as shown in FIG. 26B, and it is possible to prevent a space 301 causing the peeling between a tungsten nitride film 15 and a polysilicon film 14 from being generated. Therefore, it is possible to prevent the increase of contact resistance. In order to prevent the peeling, at least the silicon nitride film 17 may be formed on the upper surface of the tungsten film 16. The silicon oxide film 18 is not indispensable. Therefore, after forming the silicon nitride film 17 on the upper surface of the tungsten film 16 and then annealing it for 8 seconds at 1000° C., the silicon oxide film 18 may be formed.

In this embodiment, after the tungsten nitride film 15 and tungsten film 16 are formed on the polysilicon film 14, the tungsten film 16 is annealed in a state in which the silicon nitride film 17 and silicon oxide film 18 further are formed on the tungsten film 16. Such annealing reduces the resistance of the tungsten film 16 and prevents the peeling between the tungsten nitride film 15 and polysilicon film 14 from generating. It is conceivable that the tungsten film 16 expands in a horizontal direction thereof due to the change of grain diameter thereof, and the tungsten film is locally lifted up so as to relax the expansion thereof, thereby generating the above peeling at the boundary between the tungsten nitride film 15 and polysilicon film 14, the boundary having the weakest adhesion properties. In this embodiment, since the silicon nitride film 17 is formed on the surface of the tungsten film 16, the surface of the tungsten film 16 is physically fixed by the silicon nitride film 17, the form change of the tungsten film 16 is inhibited. Moreover, since the silicon nitride film 17 itself has stress which shrinks it, the expansion of the tungsten film 16 is inhibited, thereby contributing to no peeling.

Also, in forming a buried gate electrode subject to annealing in the step shown in FIG. 10, although a silicon nitride film is not formed on the upper surface of a tungsten film 10, peeling is not caused, because a film under tungsten film 10 is a silicon oxide film, not a silicon film. Although peeling has not been caused, in order to avoid the oxidation of the surface of the tungsten film 10, after forming the tungsten film 10 on the entire surface of the semiconductor substrate, it is possible to perform annealing while laminating a silicon nitride film on the upper surface of the tungsten film as the formation of bit line, and thereafter, to form a buried gate electrode by etching back the silicon nitride film and tungsten film.

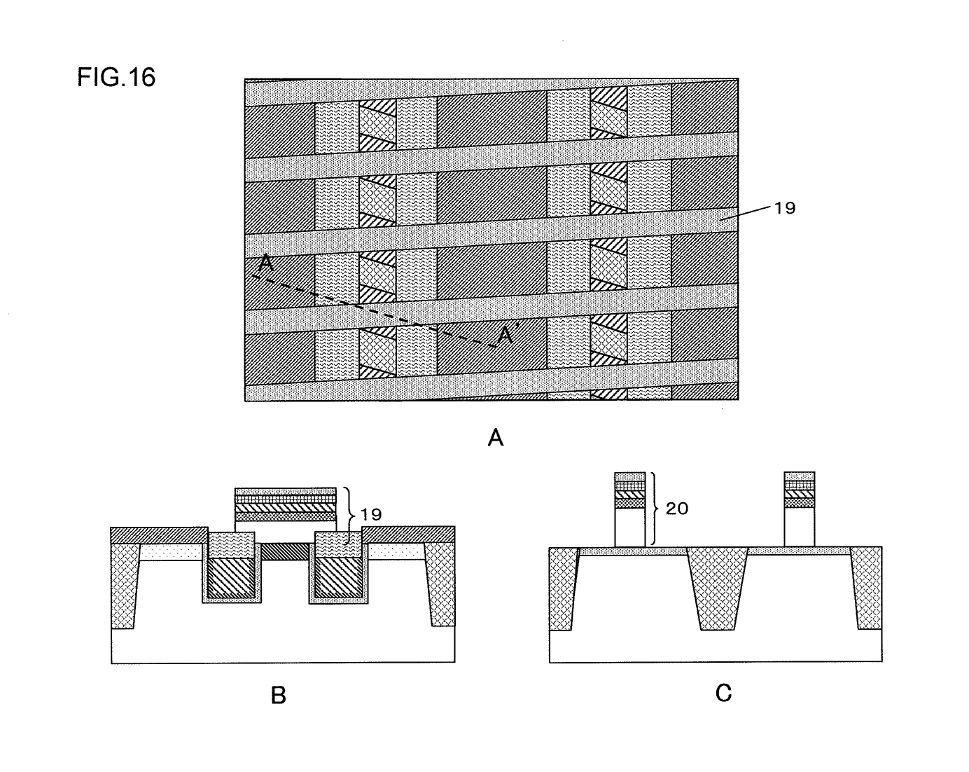

As shown in FIG. 16, a laminate body is etched using lithography, to form a bit line 19 comprising the laminate body in a memory cell region. At this time, a gate electrode 20 for a planar-type MOS gate transistor comprising a laminate body is simultaneously formed in a peripheral circuit region. The bit line 19 has a large width in FIG. 16B. This is because as since FIG. 16A (plane view) show a cross section which is slanted to the bit line. The shortest width of the bit line is identical to or smaller than the gate electrode 20. In this embodiment, the width of the bit line 19 is 40 nm in a buried gate electrode extending direction and the width of the gate electrode 20 formed in a peripheral circuit region is 60 nm. As mentioned above, although FIG. 26C is an enlarged view of the gate electrode 20, the tungsten film 16 comprises at least single crystal grains 302 crossing the gate electrode 20 in a width direction.

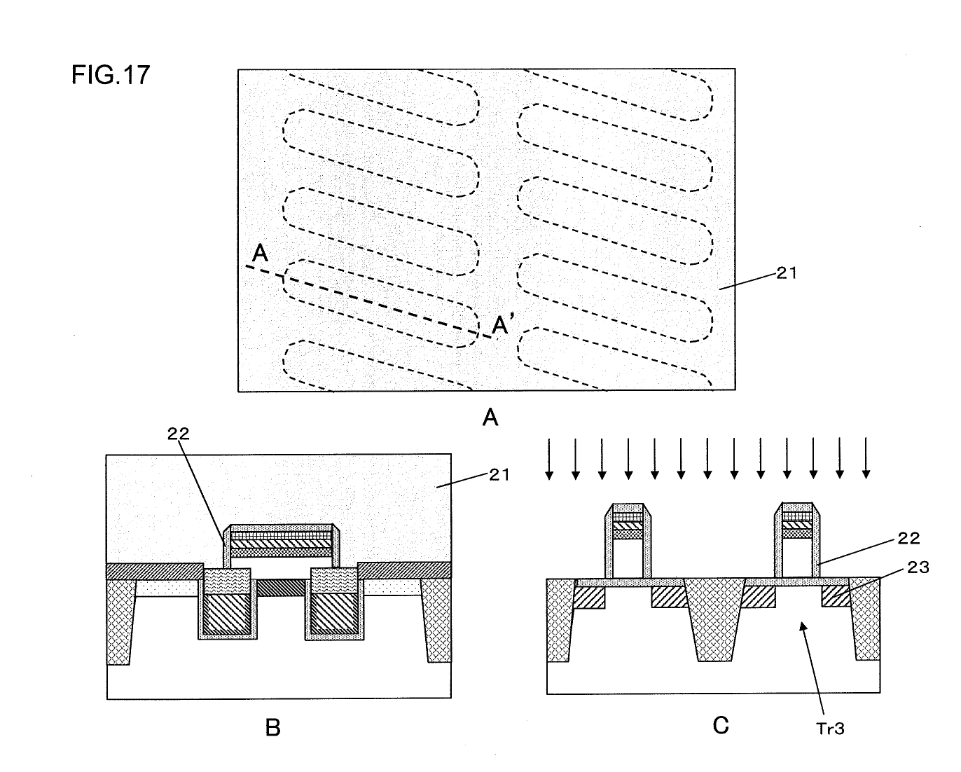

As shown in FIG. 17, after forming a silicon nitride film on the entire surface of the semiconductor substrate, the silicon nitride film is etched back by dry etching. Subsequently, a side wall 22 is formed on a side wall of a bit line 19 and a gate electrode 20. FIG. 26C is an enlarged view of FIG. 17C. By the annealing of FIG. 15, a tungsten film 16 has at least single crystal grain 302 crossing the gate electrode 20 in a width direction. The single crystal grain 302 comprises two edge surfaces corresponding to the sidewalls of the gate electrode 20 and the two edge surfaces are adjacent to the inner surfaces of the sidewalls 22. As a result, the grain boundary preventing charge transfer highly reduces, thereby reducing resistance of the tungsten film. Subsequently, n-type impurity of phosphorous, arsenic, etc. is ion-injected into the peripheral circuit region while covering a memory cell region with a photoresist 21, to form source and drain regions 23 in the region of semiconductor substrate located in both sides of the gate electrode 20. As a result, a planar-type MOS transistor Tr3 is completed. Thereafter, the photoresist 21 formed on the memory cell region is removed.

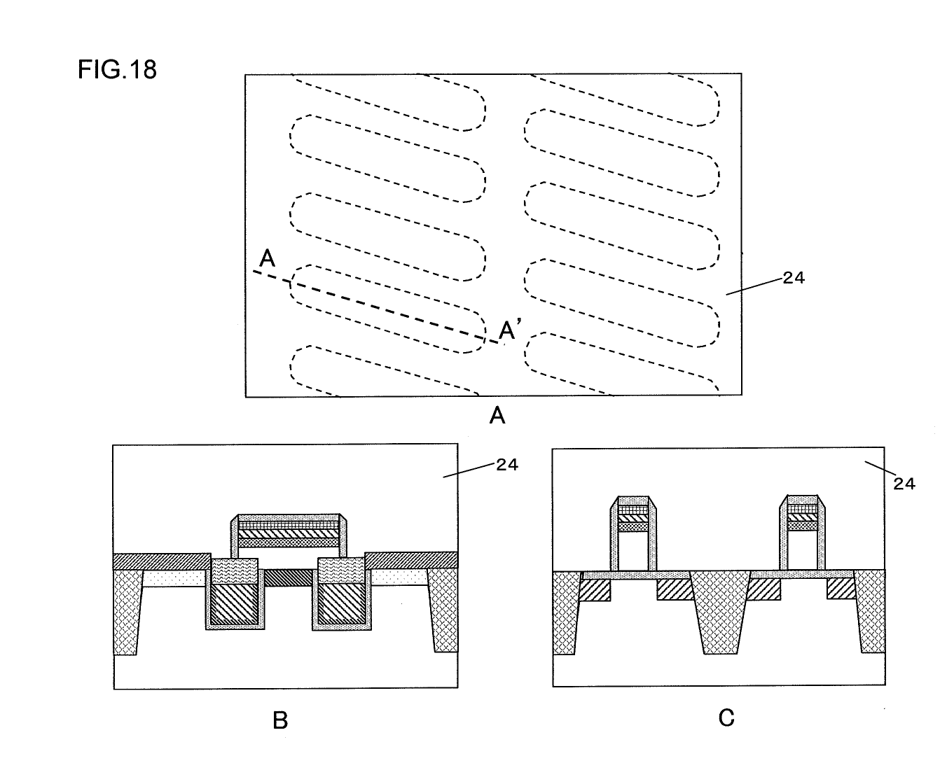

As shown in FIG. 18, an interlayer insulating film 24 having a thickness of 400 nm is formed on the entire surface of a semiconductor substrate. Thereafter, the surface of the interlayer insulating film 24 is flatten by CMP, so that the interlayer insulating film 24 has a thickness of 250 nm.

As shown in FIG. 19, a contact hole 25 is formed by lithography and dry etching such that the contact hole 25 penetrates through an interlayer insulating film 24 and a hard mask 5 in a memory cell region, to expose a drain region 43. After forming the contact hole 25, the mask formed by lithography is removed. The contact hole 25 has a diameter of 50 nm. Subsequently, a silicon film containing phosphorous of 1×10²⁰ atoms/cm³ is formed on the entire surface of the semiconductor substrate by CVD, so that the contact hole 25 is completely buried. Subsequently, the silicon film is etched back by dry etching, to form a silicon plug 26 inside the contact hole 25. The height of the upper surface of the silicon plug 26 is 100 nm upward from the surface of a semiconductor substrate. After forming the silicon plug 26 with non-doped silicon, impurity may be introduced into the non-doped silicon by ion injection. Also, the silicon plug 26 may be formed by selective epitaxial growth.

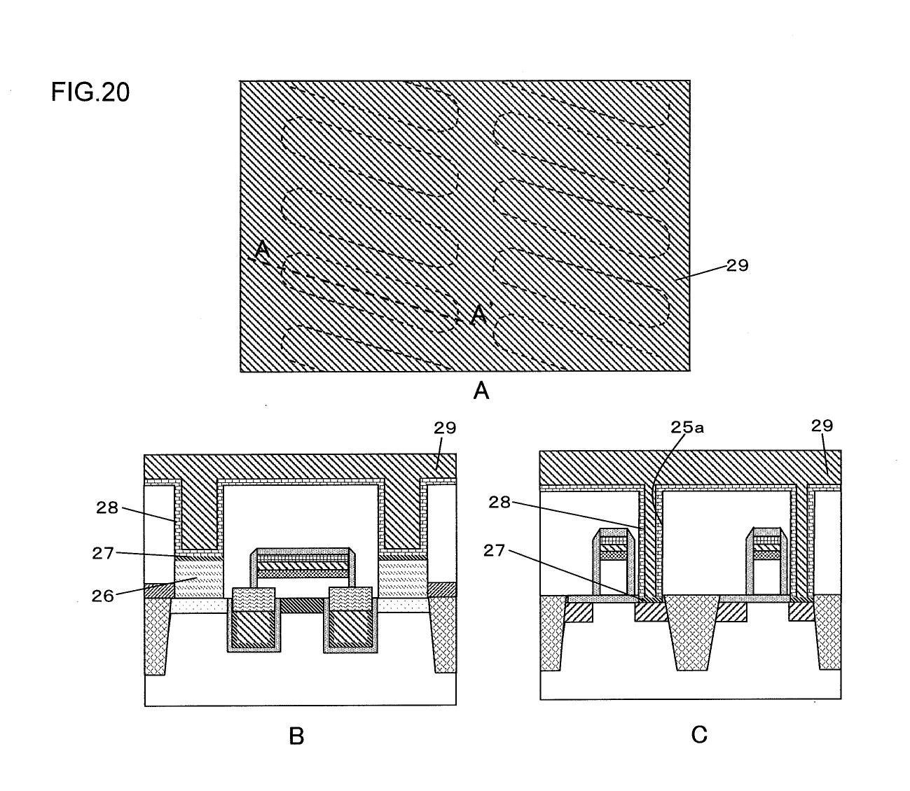

As shown in FIG. 20, a peripheral contact hole 25a is formed by lithography and dry etching such that the peripheral contact hole 25a penetrates through an interlayer insulating film 24 and a gate oxide film 3 in a peripheral circuit region to expose a source or drain region 23 in the memory cell region. The peripheral contact hole 25a has a diameter of 60 nm. Subsequently, the mask formed by lithography is removed. Thereafter, a titanium film 27 having a thickness of 5 nm and a titanium nitride film 28 having a thickness of 10 nm are formed in order on the entire surface of a semiconductor substrate by CVD. Subsequently, a tungsten film 29 is formed on the entire surface of the semiconductor substrate by SFD, so that the peripheral contact hole 25a is completely buried. The tungsten film 29 is formed so as to have a thickness of 50 nm under the same condition as a tungsten film 10. Subsequently, the tungsten film 29 is annealed for 8 seconds at 1000° C. Such annealing increases the diameter of the crystal grains in the tungsten film 29, as in the tungsten film 10 for a buried gate electrode in FIG. 24, thereby reducing resistance of the tungsten film. The tungsten film 29 comprises at least a single crystal grain crossing the contact hole 25a in a width direction.

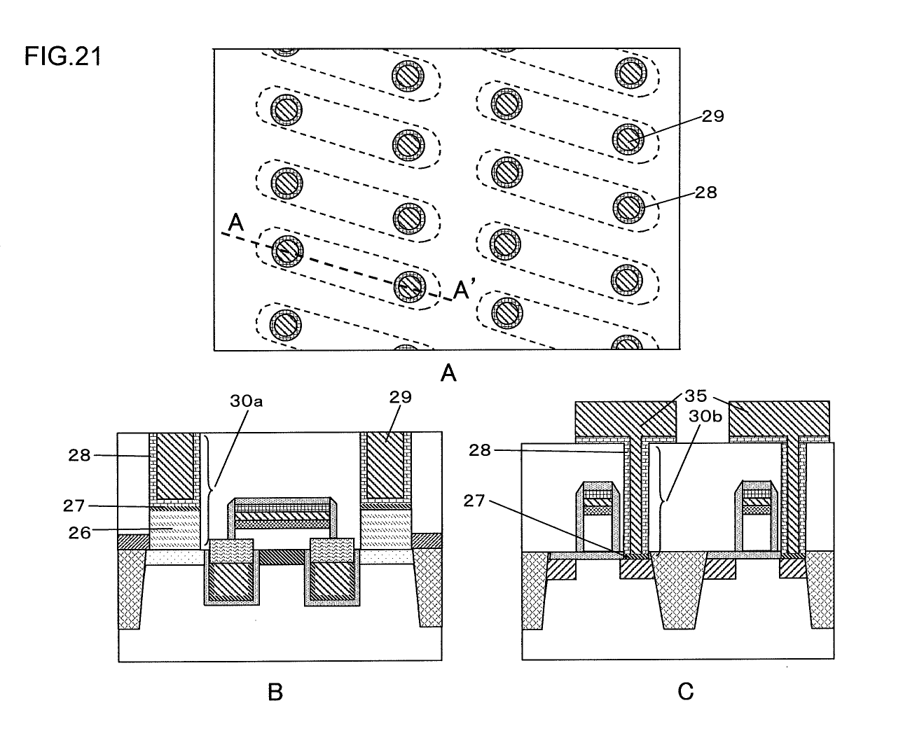

As shown in FIG. 21, after forming photoresist (not shown) on the entire surface of the memory cell region and the wiring-forming region of the peripheral circuit region, a contact plug 30b and a wiring are formed by etching a tungsten film 29 provided in a peripheral circuit region. After removing the photoresist, photoresist (not shown) is formed in the peripheral circuit region, and a contact plug 30a is formed by further etching the tungsten film 29 and titanium nitride film 28 provided in the memory cell region Thereafter, the photoresist is removed. With respect to forming the contact plugs 30a and 30b, there are a silicon substrate 50 or a silicon film 26 in the lower layer when annealing the tungsten film 29. But, unlike the formation of bit line, the tungsten film 29 is not peeled, because there is a very small contact area between the tungsten film and lower layer. Although the tungsten film 29 is not peeled, in order to prevent it from being oxidized, it may be annealed while a silicon nitride film is laminated on the upper surface of the tungsten film 29.

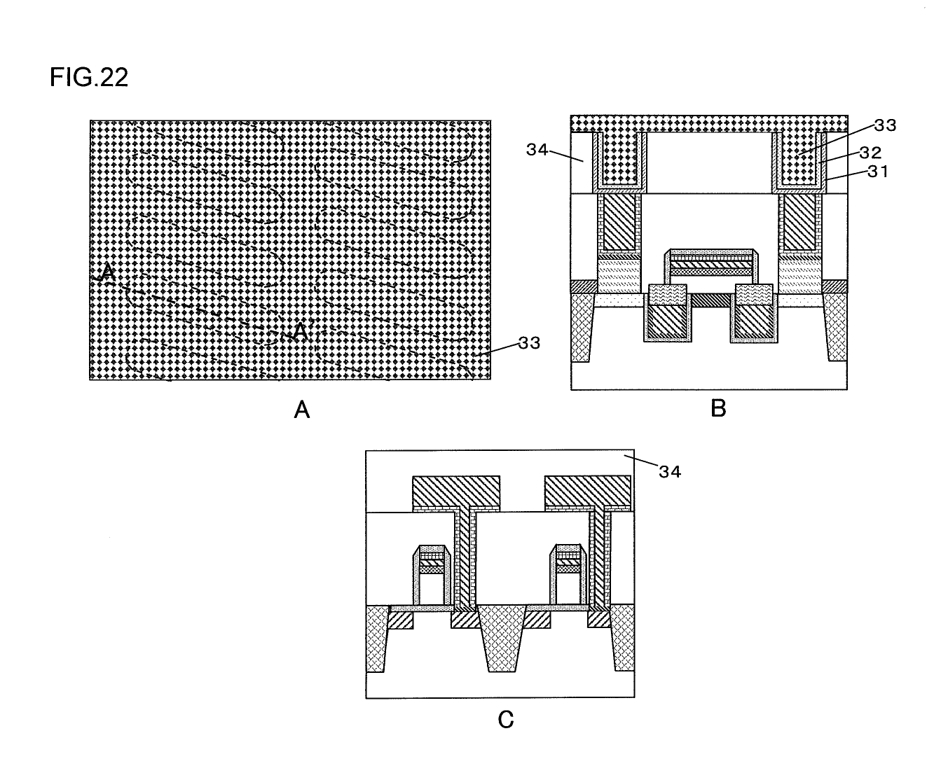

As shown in FIG. 22, after forming an interlayer insulating film 34 on the entire surface of the semiconductor substrate, a capacitor hole is formed inside the interlayer insulating film 34, so that a contact plug in a memory cell region is exposed. In the memory cell region, a capacitor comprising a lower electrode 31, a capacitor insulating film 32, and an upper electrode 33 in order is formed inside the capacitor hole so as to connected to a contact plug 30a. As a result, it is possible to complete DRAM comprising a plurality of memory cells which includes a capacitor and an MOS transistor connected to the capacitor.

As mentioned above, in this embodiment, a tungsten film is used when forming a buried gate electrode, a bit line, a gate electrode for a planar-type MOS transistor, and a contact plug. After forming a tungsten film and before etching back or etching the tungsten film, the tungsten film is annealed. As a result, it is possible to reduce the resistance of the tungsten film, thereby providing a high performance semiconductor device capable for correspondence to miniaturization.

### Second Exemplary Embodiment

This embodiment shows the condition available for SFD used in the first exemplary embodiment. Specifically, when forming a tungsten films 10, 16, and 29, this embodiment uses SFD method. The SFD method comprises a nucleus forming process for forming a crystalline nucleus of tungsten by ALD (Atomic layer Deposition), and a film forming process for forming a tungsten film on a crystalline nucleus by CVD, continuously. In ALD, a cycle of steps (1) to (4) below is performed several times. In CVD, the step (5) below is performed.

(1) supplying first material gas to adsorb a tungsten material on the surface of a lower film;

(2) pursing the first material gas;

(3) supplying first reduction gas to reduce the tungsten material adsorbed on the surface of lower film, thereby forming a tungsten crystalline nucleus;

(4) pursing the first reduction gas; and

(5) simultaneously supplying second material gas and second reduction gas to form a tungsten film.

Tungsten fluoride (WF₆) gas, etc. comprising tungsten may be used as the first and second material gases. Monosilane (SiH₄) gas and diborane (B₂H₆) gas may be used as the first reduction gas. Preferably, diborane (B₂H₆) gas is used among these gases, because it has a large crystal grain diameter when forming the tungsten film and can increase a resistance reduction rate of the tungsten film after annealing. Hydrogen gas may be used as the second reduction gas. Also, the temperature when forming the tungsten film is not limited to a particular temperature, but may be 350 to 450° C.

It is apparent that the present invention is not limited to the above embodiments, but may be modified and changed without departing from the scope and spirit of the invention.

1. A method for manufacturing a semiconductor device, comprising:
forming an opening in a substrate;
forming a tungsten film on the substrate so as to fill up inside the opening;
annealing the tungsten film; and
etching back the tungsten film so that the tungsten film remains inside the opening, after annealing the tungsten film.

2. The method for manufacturing a semiconductor device according to claim 1,
wherein the substrate is a semiconductor substrate,
in forming the opening, a trench is formed as the opening,
after forming the opening and before forming the tungsten film, the method further comprises forming a gate oxide film and a titanium nitride film in this order on an inner wall of the opening,
in forming the tungsten film, the tungsten film is formed on the titanium nitride film,
in etching back the tungsten film, the titanium nitride film and the tungsten film are etched back so that the titanium nitride film and the tungsten film remain inside the opening, to form a buried gate electrode, and
the method further comprises forming source and drain regions inside the semiconductor substrate in opposite sides of the opening, to form an MOS transistor including the buried gate electrode.

3. The method for manufacturing a semiconductor device according to claim 1,
wherein the substrate is a semiconductor substrate in which an interlayer insulating film is formed thereon,
in forming the opening, a contact hole is formed inside the interlayer insulating film as the opening so as to expose the semiconductor substrate,
after forming the opening and before forming the tungsten film, the method further comprises forming a polysilicon film and a titanium film in this order in a lower portion of the opening and thereafter forming a titanium nitride film on an inner wall of an upper portion of the opening and on a surface of the interlayer insulating film,
in forming the tungsten film, the tungsten film is formed on the titanium nitride film, and
in etching back the tungsten film, the titanium nitride film and the tungsten film are etched back so that the titanium nitride film and the tungsten film remain inside the opening, to form a contact plug comprising the polysilicon film, the titanium film, the titanium nitride film, and the tungsten film inside the opening.

4. The method for manufacturing a semiconductor device according to claim 3,
wherein the method further comprises forming a capacitor so as to being electrically connected to the contact plug, after etching back the tungsten film.

5. The method for manufacturing a semiconductor device according to claim 1,
wherein an aspect ratio of the opening is 10 or less.

6. A method for manufacturing a semiconductor device, comprising:
forming a laminate body comprising a tungsten film and an insulating film on the tungsten film, on a substrate;
annealing the laminate body; and
etching the laminate body after annealing the laminate body.

7. The method for manufacturing a semiconductor device according to claim 6,
wherein the substrate is a semiconductor substrate,
in forming the laminate body, the laminate body is formed, the laminate body comprising a polysilicon film, a tungsten silicide film, a tungsten nitride film, the tungsten film, and the insulating film in this order from the semiconductor substrate, and
in etching the laminate body, the laminate body is etched to form a bit line.

8. The method for manufacturing a semiconductor device according to claim 6,
wherein the substrate is a semiconductor substrate in which a gate oxide film is formed on a surface thereof,
in forming the laminate body, the laminate body is formed, the laminate body comprising a polysilicon film, a tungsten silicide film, a tungsten nitride film, the tungsten film, and the insulating film in this order from the semiconductor substrate,
in etching the laminate body, the laminate body is etched to form a gate electrode, and
the method further comprises forming source and drain regions inside the semiconductor substrate in opposite sides of the gate electrode, to obtain a planar-type MOS, after etching the laminate body.

9. The method for manufacturing a semiconductor device according to claim 1,
wherein annealing is performed at 800 to 1000° C.

10. The method for manufacturing a semiconductor device according to claim 1,
wherein annealing is soak annealing or spike annealing.

11. The method for manufacturing a semiconductor device according to claim 1,
wherein in forming the tungsten film, the tungsten film is formed by SFD method which comprises forming a crystalline nucleus of tungsten by ALD, and forming the tungsten film on the crystalline nucleus by CVD, continuously,
wherein in the ALD, a cycle of steps (1) to (4) below is repetitively performed a plurality of times, and
in the CVD, step (5) below is performed;
(1) supplying a first material gas to adsorb a tungsten material on a surface of a lower film;
(2) pursing the first material gas;
(3) supplying a first reduction gas to reduce the tungsten material adsorbed on the surface of the lower film, to form the crystalline nucleus of tungsten;
(4) pursing the first reduction gas; and
(5) simultaneously supplying a second material gas and a second reduction gas to form the tungsten film.

12. The method for manufacturing a semiconductor device according to claim 11,
wherein the first and second material gases are tungsten fluoride (WF₆) gas,
the first reduction gas is monosilane (SiH₄) gas or diborane (B₂H₆) gas, and
the second reduction gas is hydrogen gas.

13. The method for manufacturing a semiconductor device according to claim 11,
wherein in forming the tungsten film, the tungsten film is formed by the SFD which is set in a range of 350 to 450° C.

14. A method for manufacturing a semiconductor device including a Dynamic Random Access Memory, comprising:
forming a gate oxide film on a surface of a semiconductor substrate in a peripheral circuit region;
forming a trench inside the semiconductor substrate in a memory cell region;
forming a gate oxide film and a titanium nitride film in this order on an inner wall of the trench;
forming a first tungsten film on the semiconductor substrate so as to fill up inside the trench;
annealing the first tungsten film;
etching back the titanium nitride film and the first tungsten film so that the gate oxide film, the titanium nitride film, and the first tungsten film remain inside the trench after annealing the first tungsten film;
forming first and second impurity diffusion regions in the semiconductor substrate of the memory cell region in opposite sides of the trench, to obtain an MOS transistor including a buried gate electrode;
forming a laminate body comprising a polysilicon film, a tungsten silicide film, a tungsten nitride film, a second tungsten film, a silicon nitride film, and a silicon oxide film in this order on the semiconductor substrate in the memory cell region and the peripheral circuit region;
annealing the laminate body;
etching the laminate body after annealing the laminate body, to form a bit line on the first impurity diffusion region in the memory cell region and to form a gate electrode on the gate oxide film in the peripheral circuit region;
forming first and second impurity diffusion regions in the semiconductor substrate of the peripheral circuit region in opposite sides of gate electrode, to obtain a planar-type MOS transistor;
forming an interlayer insulating film on the semiconductor substrate of the memory cell region and the peripheral circuit region;
forming a contact hole inside the interlayer insulating film in the memory cell region so as to expose the second impurity diffusion region;
forming a polysilicon film and a titanium film in this order in a lower portion of the contact hole;
forming a titanium nitride film on an inner wall of an upper portion of the contact hole and on a surface of the interlayer insulating film;
forming a third tungsten film so as to fill up inside the contact hole and cover the titanium nitride film on the interlayer insulating film;
annealing the third tungsten film;
etching back the titanium nitride film and the third tungsten film so that the polysilicon film, the titanium film, the titanium nitride film, and the third tungsten film remain inside the contact hole, after annealing the third tungsten film, to form a capacitor contact plug; and
forming a capacitor so as to be connected to the capacitor contact plug.

15. A semiconductor device comprising a tungsten wiring,
wherein at least one crystal grain in the tungsten wiring has a diameter equal to or greater than a width of the tungsten wiring.

16. The semiconductor device according to claim 15,
wherein the semiconductor device comprises:
a semiconductor substrate; and
an MOS transistor including a buried gate electrode, and
wherein the buried gate electrode comprises:
a gate oxide film, and a titanium nitride film formed in this order on an inner wall of a trench in the semiconductor substrate; and
the tungsten wiring formed on the titanium nitride film so as to fill up inside the trench.

17. The semiconductor device according to claim 15,
wherein the semiconductor device comprises:
a semiconductor substrate;
an interlayer insulating film formed on the semiconductor substrate; and
a contact plug penetrating through the interlayer insulating film and contacting with a main surface of the semiconductor substrate, and
wherein the contact plug comprises:
a polysilicon film and a titanium film formed in this order in a lower portion of a contact hole;
a titanium nitride film formed on an inner wall of an upper portion of the contact hole; and
the tungsten wiring formed on the titanium nitride film so as to fill up the upper portion of the contact hole.

18. The semiconductor device according to claim 17, further comprising a capacitor or a wiring layer connected to the contact plug.

19. The semiconductor device according to claim 15,
wherein the semiconductor device comprises:
a semiconductor substrate; and
a bit line formed on the semiconductor substrate, and
wherein the bit line comprises a polysilicon film, a tungsten silicide film, a tungsten nitride film, and the tungsten wiring in this order from the semiconductor substrate.

20. The semiconductor device according to claim 15,
wherein the semiconductor device comprises:
a semiconductor substrate; and
an MOS transistor including a gate electrode formed on the semiconductor substrate so that a gate oxide film is interposed between the gate electrode and the semiconductor substrate, and
wherein the gate electrode comprises a polysilicon film, a tungsten silicide film, a tungsten nitride film, and the tungsten wiring in this order from the semiconductor substrate.
